(19) United States
(12) Patent Application Publication
(10) Pub. No.: US 2015/0010166 A1
(43) Pub. Date: Jan. 8, 2015

(54) SOUND ENHANCEMENT FOR HOME THEATERS

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/188,606

(22) Filed: Feb. 24, 2014

Related U.S. Application Data
(60) Provisional application No. 61/768,299, filed on Feb. 22, 2013.

(51) Int. Cl. H03G 5/16

(52) U.S. Cl. CPC H03G 5/16
USPC 381/101

(57) ABSTRACT

A method and process and system for enhancing and customizing movie theatre sound includes receiving an input audio sound and enhancing the received sound. The enhanced audio sound is subsequently tone adjusted to create a tone adjusted enhanced sound, which is then outputted. The enhancement includes the parallel processing the input audio via a low pass filter with dynamic offset, an envelope controlled bandpass filter, a high pass filter, adding an amount of dynamic synthesized sub bass to the audio and combining the four treated audio signals in a summing mixer with the original audio. The tone adjustment includes a first section for adjusting a low frequency tone, a second section for adjusting a mid frequency tone, a third section for adjusting a high frequency tone and mixing the audio outputs processed by the first, second and third sections to produce a tone adjusted enhanced audio sound.

### CROSS-REFERENCE TO RELATED PATENT APPLICATIONS

Embodiments of the present invention relate to U.S. Provisional Application Ser. No. 61/768,299, filed Feb. 22, 2013, entitled “HOME THEATER SOUND SYSTEM”, the contents of which are incorporated by reference herein and which is a basis for a claim of priority.

### BACKGROUND OF THE INVENTION

Home cinema, conventionally known as home theatre, refers to home entertainment systems that seek to reproduce a movie theater experience and mood, with the help of video and audio equipment in or outside a private home¹. ¹ http://en.wikipedia.org/wiki/Home cinema

A “home theater in a box” (HTIB) is an integrated home theater package which “bundles” together a combination DVD or Blu-ray player, a multi-channel amplifier (which includes a surround sound decoder, a radio tuner, and other features), speaker wires, connection cables, a remote control, a set of five or more surround sound speakers (or more rarely, just left and right speakers) and a low-frequency subwoofer². ² http://en.wikipedia.org/wiki/Home theater in a box

The quality of the conventional home theatre systems varies widely, depending on the price of such systems. They object of the conventional home theatre sound systems is to make the audio sound as if user is in a movie theater, with all the dynamic and harmonic content of the same. Seldom do these common systems achieve this level of quality.

There is a need for a home theatre entertainment system that addresses the above deficiencies of the conventional systems.

### SUMMARY OF THE PREFERRED EMBODIMENT(S)

The inventive system and process of the present invention is preferably a DSP process implemented into an AV type receiver/playback system.

The inventive process and system Home Theater Sound System is commonly used for home theater systems. In a typical system there will be 6 audio channels that will be specific inputs into the system. They are: 1.) Left Out, 2.) Right Out, 3.) Rear Left Out, 4.) Rear Right Out, 5.) Center Out, and 6.) LFE Out. These outputs together represent the audio outputs of a 5.1 surround system. Each of these outputs flow into the corresponding MS channel or input. The MS process will work in pairs for this application, except for the LFE processor.

According to an exemplary embodiment, the inventive process, as shown in FIG. 4 is set up as follows: Left/Right—signal flow as chart designates. Rear Left/Rear Right—Signal flow as chart designates. Center—This is a mono signal split into two mono signals (dual mono) and follows the signal flow as chart designates. LFE—This is the SUB BASS portion of the process only. No other modules are needed for this.

To expand to other sizes (formats) such as 7.1, one would just create more of the appropriate processes in the system. For example a 7.1 system would add two mid/side speakers to the existing system.

This type of system typically would use some type of decoder like DTS, Dolby, SDDS, etc. Those processes would split the audio into single channels for processing and continuing the signal path inside of a home theater device or receiver.

### BRIEF DESCRIPTION OF THE DRAWINGS

FIG. 1 is a block diagram of the basic signal flow according to an embodiment of the present invention.

FIG. 2 shows a typical use/implementation of the inventive Max Sound Processor according to an embodiment of the present invention.

FIG. 3 shows a typical steps involved in the inventive Max Sound Processor according to an embodiment of the present invention.

FIG. 4 is a block diagram of the Wave Adjustment Tool (WAT) according to the present invention.

FIG. 5 is a flow chart of the application of the set up of the present invention according to an exemplary embodiment.

### DETAILED DESCRIPTION OF THE PREFERRED EMBODIMENT(S)

The inventive process of the present application includes two stages, a Stereo Processing module (also referred to as the Max Sound Processor herein) and a tone adjustment module (also referenced as the Wave Adjustment Tool (WAT)).

The details of the present invention will now be further explained by reference to the drawings.

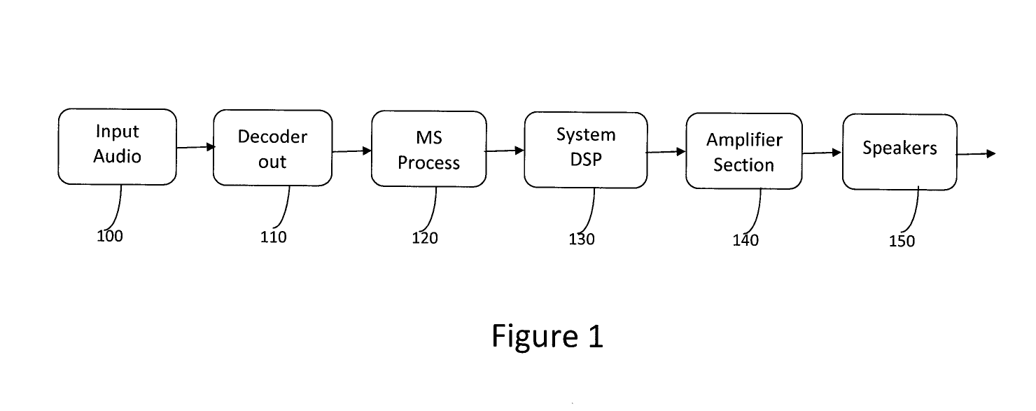

Referring to FIG. 1, stereo audio input 100 is audio is received and is fed to decoder unit 110, e.g., DTS, Dolby, SDDS, etc, which would split the audio into single channels for processing. Output from the decoder unit 110 is processed by the Max Sound Process 120, which is further explained below, and continues inside of a home theater device or receiver (130, 140) to the speaker (150).

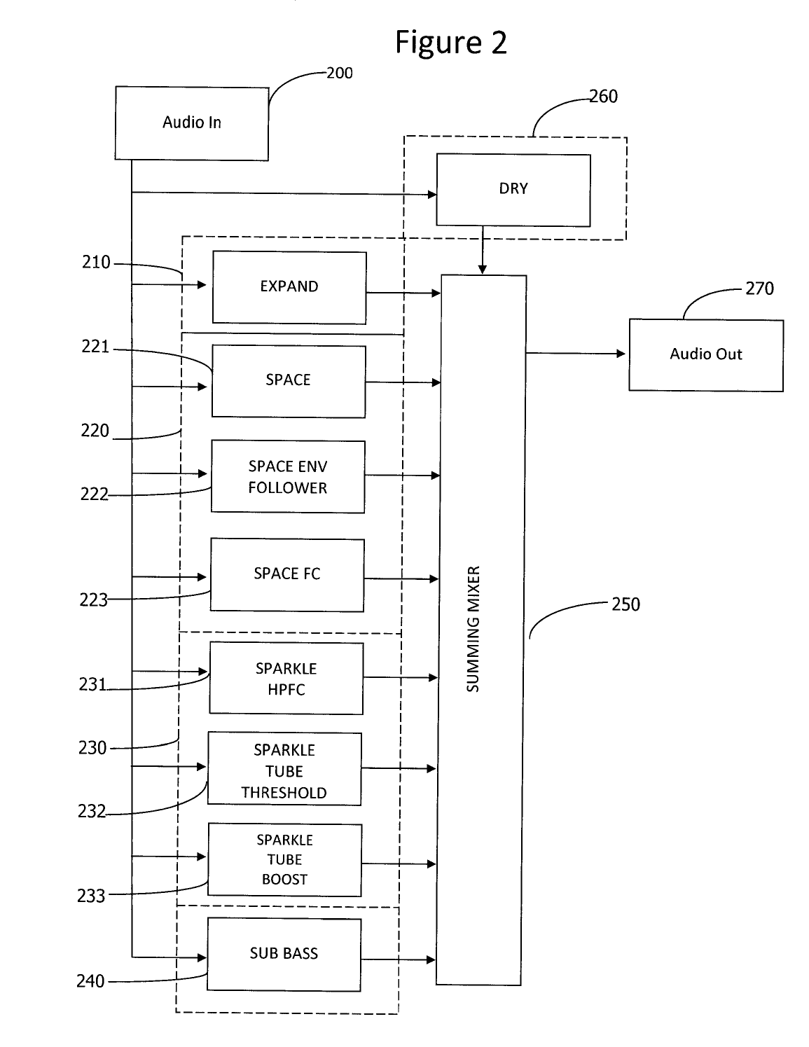

Further details of the inventive Stereo Processor will now be described with reference to FIG. 2. Stereo Audio input 200 is processed, in parallel, by several module as follows. EXPAND 210 is preferably a 4 pole digital low pass filter with an envelope follower for dynamic offset (fixed envelope follower). This allows the output of the filter to be dynamically controlled so that the output level is equal to whatever the input is to this filter section. For e.g., if the level at the input is −6 dB, then the output will match that. Moreover, whenever there is a change at the input, the same change will occur at the output regardless of either positive or negative amounts. The frequency for this filter is, e.g., 20 to 20 k hertz, which corresponds to a full range. In one embodiment, the purpose of EXPAND 210 is to “warm up” or provide a fuller sound as waveform 100 passes through it. The original audio 200 passes through, and is added to the effected sound for its output. As the input amount varies, so does the phase of this section. This applies to all filters used in this software application. Preferably all filters are of the Butterworth type.

Next, we discuss SPACE 220. SPACE 220 refers to the block of three modules identified by reference numerals 221, 222 and 223. The first module SPACE 221—which follows EXPAND 210 envelope follower, sets the final level of this module. This is the effected signal only, without the original. SPACE ENV FOLLOWER 222 tracks the input amount and forces the output level of this section to match. SPACE FC 223 sets the center frequency of the 4 pole digital high pass filter used in this section. This filter also changes phase as does EXPAND 210.

SPACE blocks 220 are followed by the SPARKLE 230 blocks. Like SPACE 220, there are several components to SPARKLE. SPARKLE HPFC 231 is a 2 pole high pass filter with a preboost which sets the lower frequency limit of this filter. Anything above this setting passes through the filter while anything below is discarded or stopped from passing. SPARKLE TUBE THRESH 232 sets the lower level at which the tube simulator begins working. As the input increases, so does the amount of the tube sound. The tube sound adds harmonics, compression and a slight bit of distortion to the input audio 200. This amount increases slightly as the input level increases. SPARKLE TUBE BOOST 233 sets the final level of the output of this module. This is the effected signal only, without the original.

Next, the SUB BASS 240 module is discussed. This module takes the input signal and uses a low pass filter to set the upper frequency limit to about 100 Hz. An octave divider occurs in the software that changes the input signal to lower by an octave (12 semi tones) and output to the only control in the interface, which is the level or the final amount. This is the effected signal only, without the original.

Outputs from the above modules 210 to 240 are directed into SUMMING MIXER 250 which combines the audio. The levels going into the summing mixer 250 are controlled by the various outputs of the modules listed above. As they all combine with the original signal 200 fed through the DRY 260 module there is interaction in phase, time and frequencies that occur dynamically. These changes all combine to create a very pleasing audio experience for the listener in the form of “enhanced” audio content. For example, a change in a single module can have a great affect on what happens in relation to the other modules final sound or the final harmonic output of the entire software application.

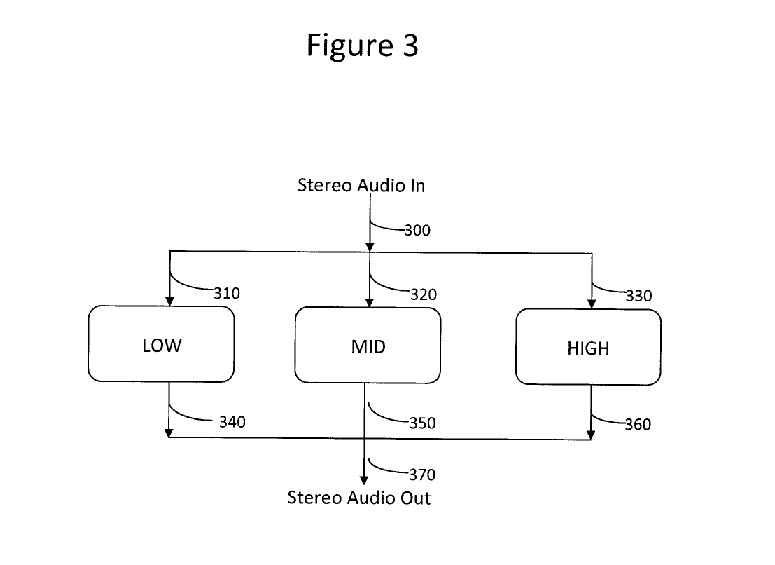

Continuing with reference to FIG. 3, output from the Stereo Processor of FIG. 1 (120) is received for further processing by the Wave Adjustment Tool (130 in FIG. 1) of the present invention for tone adjustment as input audio 300. Input audio 300 is processed in parallel by the three sections of the WAT tone adjusting circuit, which include the LOW 310, MID 320 and HIGH 330 sections. The audio processed by the three sections (shown by reference numerals 340, 350 and 360 in FIG. 2) are then mixed to form output audio 370.

According to one embodiment of the present invention the LOW section has a frequency of 100 Hz and a 0.5 bandwidth; MID has a frequency of 2500 Hz with an adjustable bandwidth; and HIGH has a 10 kHz frequency and an adjustable bandwidth.

For MID, the center frequency is dynamically moved in both positive and negative amounts according to the input level of this bandpass filter. Preferably, the range is from 1.7 kHz on the low end to 4.5 kHz on the upper end with 2.5 kHz as the center or nominal setting. As the input level goes positive or negative, so the bandwidth will change. For a negative change the bandwidth will increase, for e.g., to a 0.5, while a positive change will decrease, for e.g., to a 0.1. This provides a larger frequency change for negative and a smaller, more precise change for positive level amounts in the filtered audio content.

In reference to the HIGH tone control section the center frequency is fixed, e.g., at 10 kHz, but the bandwidth changes dynamically in positive amounts as the input level changes. For negative amounts the bandwidth stays at, e.g., 0.5, when the level decreases the bandwidth goes only to a max bandwidth of e.g., 0.3.

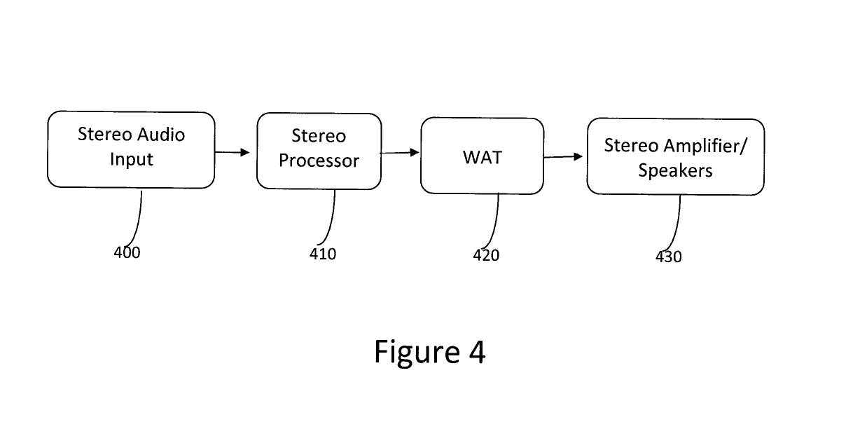

FIG. 4 is a block diagram showing the various steps according to an embodiment of the present invention. Stereo Audio Input 400 is processed by the inventive Max Sound Processor 410 and the inventive Wave Adjustment Tool (420) and received by the speakers 430 for use by listeners.

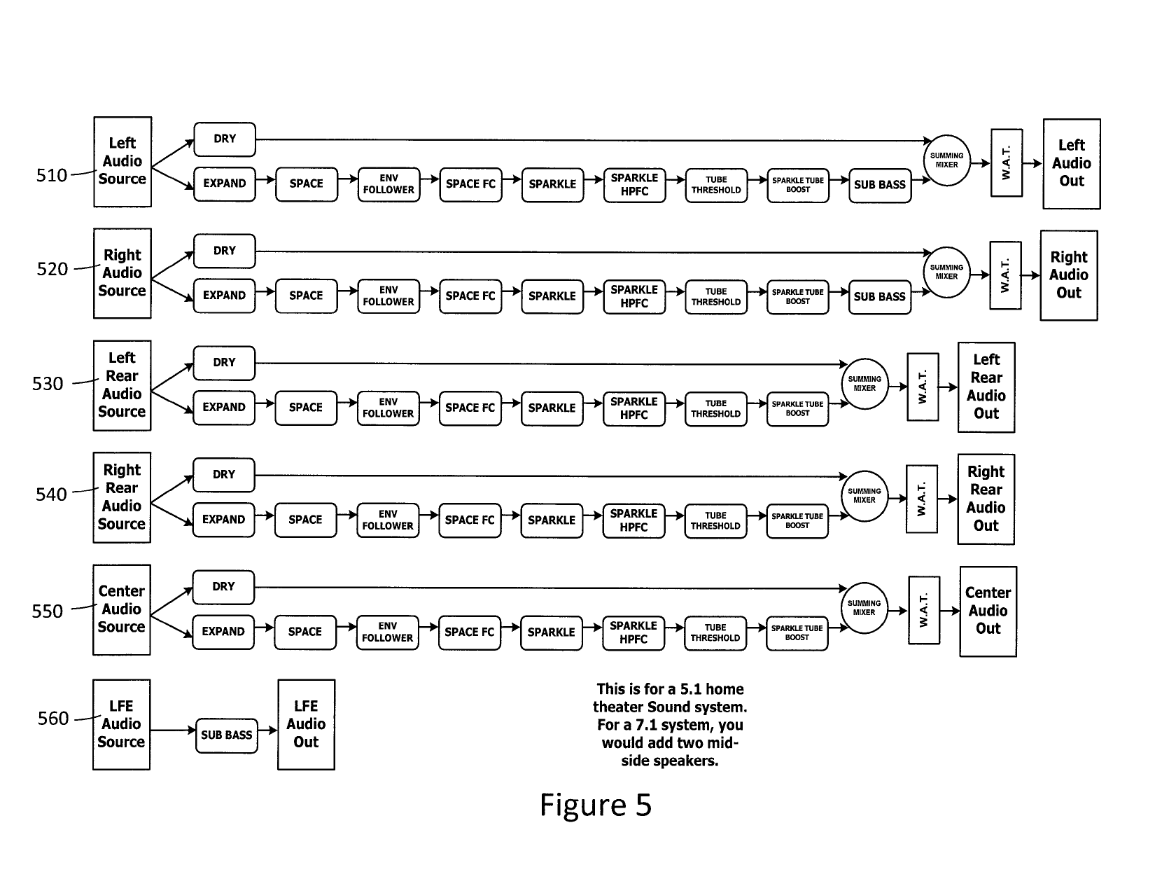

FIG. 5 is an exemplary set up of the present invention. With reference to FIG. 5, Left/Right 510 and 520—show signal flow as chart designates; Rear Left/Rear Right 530 and 540—show signal flow as chart designates; Center 550 is a mono signal split into two mono signals (dual mono) and follows the signal flow as chart designates. It is summed together as a mono output; LFE 560 is the SUB BASS portion of the process only. No other modules are needed for this. To expand to other sizes (formats) such as 7.1, you would just create more of the appropriate processes in the system. For example a 7.1 system would add two mid/side speakers to the existing system. This type of system typically would require some type of decoder before it such as DTS, Dolby, SDDS, etc. Those processes would split the audio into single channels for processing and continuing the signal path to the amplifier and speakers in an environment. The Stereo Max Sound Processor section contains the following parts to form the complete process.

What is claimed is:

1. A process and system for enhancing and customizing home theatre sound comprising:
Receiving an input audio sound;
Enhancing the voice audio input in two or more harmonic and dynamic ranges by re-synthesizing the audio into a full range PCM wave to create an enhanced sound;
Tone adjusting the enhanced sound to create a tone adjusted enhanced sound;
Outputting the tone adjusted enhanced sound.

2. The process of claim 1, wherein the enhancement comprises the parallel processing the input audio as follows:
A module that is a low pass filter with dynamic offset;
An envelope controlled bandpass filter;
A high pass filter;
Adding an amount of dynamic synthesized sub bass to the audio;
Combining the four treated audio signals in a summing mixer with the original audio.

3. A process of claim 1, wherein the tone adjustment comprises;
A first section for adjusting a low frequency tone;
A second section for adjusting a mid frequency tone;
A third section for adjusting a high frequency tone
Mixing the audio outputs processed by the first, second and third sections to produce an output audio sound.

4. The process of claim 3, wherein the low frequency tone has a frequency of 100 Hz and a bandwidth of 0.5.

5. The process of claim 3, wherein the mid frequency tone has a frequency of 2500 Hz and an adjustable bandwidth.

6. The process of claim 3, wherein the high frequency tone has a frequency of 10 KHz and an adjustable bandwidth.
